(19) United States
(12) Patent Application Publication
(10) Pub. No.: US 2026/0206645 A1
(43) Pub. Date: Jul. 16, 2026

(54) SEMICONDUCTOR PACKAGE INCLUDING A PLURALITY OF SEMICONDUCTOR CHIPS

(71) Applicant: SK hynix Inc., Icheon-si Gyeonggi-do (KR)

(72) Inventor: Jung Youn LEE, Icheon-si Gyeonggi-do (KR)

(73) Assignee: SK hynix Inc., Icheon-si Gyeonggi-do (KR)

(21) Appl. No.: 19/225,569

(22) Filed: Jun. 2, 2025

(30) Foreign Application Priority Data
Jan. 15, 2025 (KR) 10-2025-0005823

(51) Int. Cl. H10W 90/00; H10B 80/00; H10W 70/60; H10W 74/10; H10W 72/00; H10W 90/24

(52) U.S. Cl. CPC H10W 90/00; H10B 80/00; H10W 70/60; H10W 70/611; H10W 74/111; H10W 72/884; H10W 90/24; H10W 90/732; H10W 90/734; H10W 90/752; H10W 90/754

(57) ABSTRACT

Embodiments of the present disclosure provide a semiconductor package including a package substrate, a first semiconductor chip and a support member arranged on the package substrate, a first stack on the first semiconductor chip and the support member, a second stack including a sixth semiconductor chip, a seventh semiconductor chip, an eighth semiconductor chip, and a ninth semiconductor chip stacked on the package substrate. The seventh semiconductor chip is offset with respect to the sixth semiconductor chip so that a chip pad of the sixth semiconductor chip is exposed. The eighth semiconductor chip vertically overlaps with a chip pad of the seventh semiconductor chip, and the ninth semiconductor chip vertically overlaps with a chip pad of the eighth semiconductor chip.

### CROSS-REFERENCE TO RELATED APPLICATION

The present application claims priority under 35 U.S.C. §119(a) to Korean patent application number 10-2025-0005823 filed in the Korean Intellectual Property Office on January 15, 2025, which application is incorporated herein by reference in its entirety.

### TECHNICAL FIELD

Embodiments of the present disclosure generally relate to a semiconductor package, and more particularly, a semiconductor package including a plurality of semiconductor chips.

### BACKGROUND

Electronic products are becoming smaller while requiring high-capacity data processing. Accordingly, there is a growing need to increase the integration of semiconductor devices used in electronic products. Because it is difficult to satisfy the required functions with only a single semiconductor chip due to the limitations of integration technology, a semiconductor package can be manufactured using multiple semiconductor chips.

Even if a semiconductor package includes a plurality of semiconductor chips, it is required to be manufactured to a specified size or smaller depending on the requirements of the application in which the semiconductor package is mounted. Recently, a system-in-package (SIP) has been proposed in which a memory and a memory controller are integrated into a single package.

### SUMMARY

Embodiments of the disclosure may provide a semiconductor package including a package substrate, a first semiconductor chip and a support member arranged on the package substrate, a first stack including a second semiconductor chip, a third semiconductor chip, a fourth semiconductor chip, and fifth semiconductor chip stacked on the first semiconductor chip and the support member, a second stack including a sixth semiconductor chip, a seventh semiconductor chip, an eighth semiconductor chip, and a ninth semiconductor chip stacked on the package substrate, and a mold layer covering the first semiconductor chip, the support member, the first stack, and the second stack, wherein the second semiconductor chip, the third semiconductor chip, the fourth semiconductor chip, and the fifth semiconductor chip are stacked in a step shape so that chip pads of the second semiconductor chip, the third semiconductor chip, the fourth semiconductor chip, and the fifth semiconductor chip are exposed, wherein the seventh semiconductor chip is offset with respect to the sixth semiconductor chip so that a chip pad of the sixth semiconductor chip is exposed, wherein the eighth semiconductor chip vertically overlaps with a chip pad of the seventh semiconductor chip, and wherein the ninth semiconductor chip vertically overlaps with a chip pad of the eighth semiconductor chip.

Embodiments of the disclosure may provide a semiconductor package including a package substrate, a controller chip and a support member arranged on the package substrate, a first stack including a first memory chip, a second memory chip, a third memory chip, and a fourth memory chip stacked on the controller chip and the support member, a second stack including a fifth memory chip, a sixth memory chip, a seventh memory chip, and an eighth memory chip stacked on the package substrate, a first bonding wire connecting a first upper surface substrate pad of the package substrate and a chip pad of the first memory chip, a second bonding wire connecting the chip pad of the first memory chip and a chip pad of the second memory chip, a third bonding wire connecting the chip pad of the second memory chip and a chip pad of the third memory chip, a fourth bonding wire connecting the chip pad of the third memory chip and a chip pad of the fourth memory chip, a fifth bonding wire connecting a second upper surface substrate pad of the package substrate and a chip pad of the fifth memory chip, a sixth bonding wire connecting the chip pad of the fifth memory chip and a chip pad of the sixth memory chip, a seventh bonding wire connecting the second upper surface substrate pad and a chip pad of the seventh memory chip, an eighth bonding wire connecting the second upper surface substrate pad and a chip pad of the eighth memory chip, a mold layer covering the controller chip, the support member, the first stack and the second stack, and the first bonding wire to the eighth bonding wire, wherein the first memory chip, the second memory chip, the third memory chip and the fourth memory chip are stacked in a step shape so that the chip pad of the first memory chip, the chip pad of the second memory chip, the chip pad of the third memory chip, and the chip pad of the fourth memory chip are exposed, wherein the sixth memory chip is offset with respect to the fifth semiconductor chip so that the chip pad of the fifth memory chip is exposed, wherein a side surface of the seventh memory chip and a side surface of the eighth memory chip are vertically aligned with a side surface of the fifth semiconductor chip.

### BRIEF DESCRIPTION OF THE DRAWINGS

The present disclosure will be more fully understood from the detailed description and accompanying drawings provided below, which are provided for illustration only and are not intended to limit the present disclosure.

FIG. 1 illustrates a semiconductor package according to an embodiment of the present disclosure.

FIG. 2 is an enlarged drawing of a package substrate, a first semiconductor chip, a support member, a first stack, and a first bonding wire of FIG. 1 according to an embodiment of the present disclosure.

FIG. 3 is an enlarged drawing of a package substrate, a second stack, a second bonding wire, a third bonding wire, and a fourth bonding wire of FIG. 1 according to an embodiment of the present disclosure.

FIG. 4 is an enlarged drawing of section A of FIG. 1 according to an embodiment of the present disclosure.

FIG. 5 is a schematic plan view of a semiconductor package according to an embodiment of the present disclosure.

### DETAILED DESCRIPTION

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

The cross-hatching throughout the figures illustrates corresponding or similar areas between the figures rather than indicating the materials associated with the areas.

When one element is identified as “connected” or “coupled” to another element, the elements may be connected or coupled directly or through an intervening element between the elements. When two elements are identified as “directly connected” or “directly coupled,” one element is directly connected or directly coupled to the other element without an intervening element between the two elements.

When one element is identified as “on,” “over,” “under,” or “beneath” another element, the elements may directly contact each other or an intervening element may be disposed between the elements.

Terms such as “vertical,” “horizontal,” “above,” “below,” “on,” “side,” “upper,” “lower,” “left,” “right,” “level,” and other terms implying relative spatial relationship or orientation are utilized only for the purpose of ease of description or reference to a drawing and are not otherwise limiting. Other spatial relationships or orientations not shown in the drawings or described in the specification are possible within the scope of the present disclosure.

Terms such as “first” and “second” are used to distinguish between various elements and do not imply size, order, priority, quantity, or importance of the elements. For example, a first element may be named as a second element in one example, and the second element may be named as a first element in another example.

In the description, when an element included in an embodiment is described in singular form, the element may be interpreted to include a plurality of elements performing the same or similar functions.

While the detailed embodiments of the present disclosure are disclosed in the present disclosure, those skilled in the art will understand that various modifications, additions, and substitutions related to these embodiments are possible without departing from the scope and technical concepts of the present disclosure. Therefore, the scope of the present disclosure should not be limited to the foregoing embodiments. All changes within the meaning and range of equivalency of the claims are included within their scope.

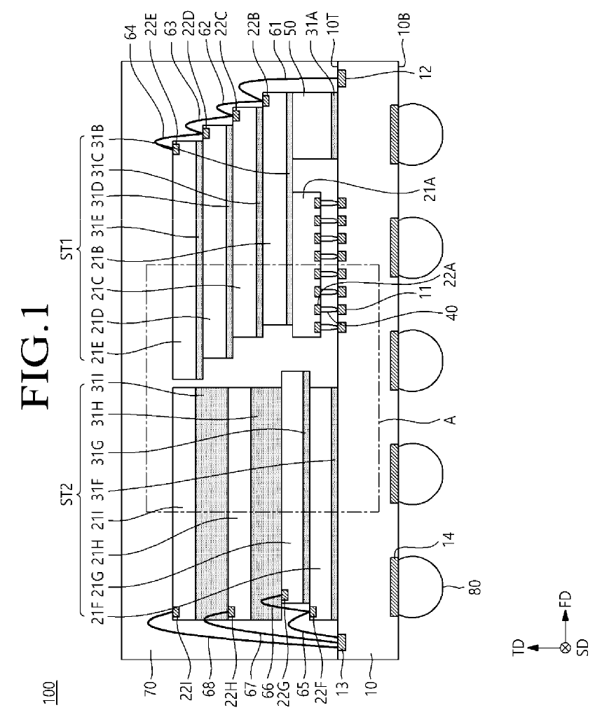

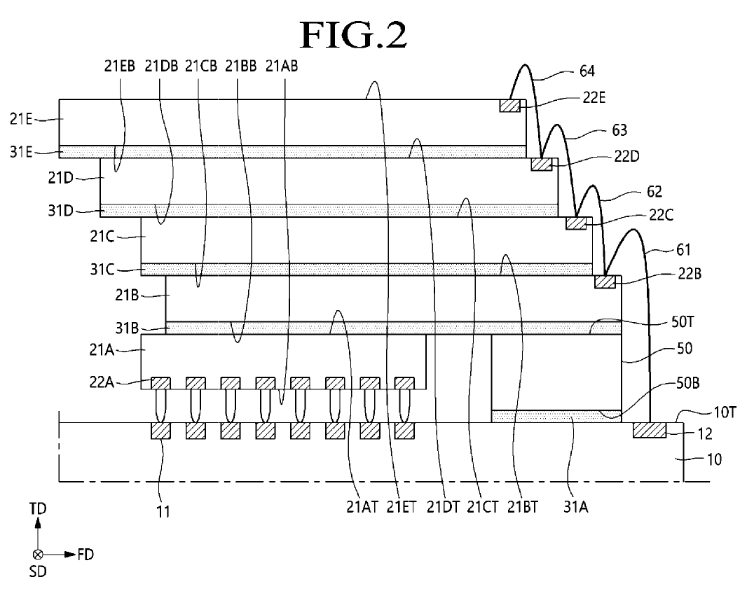

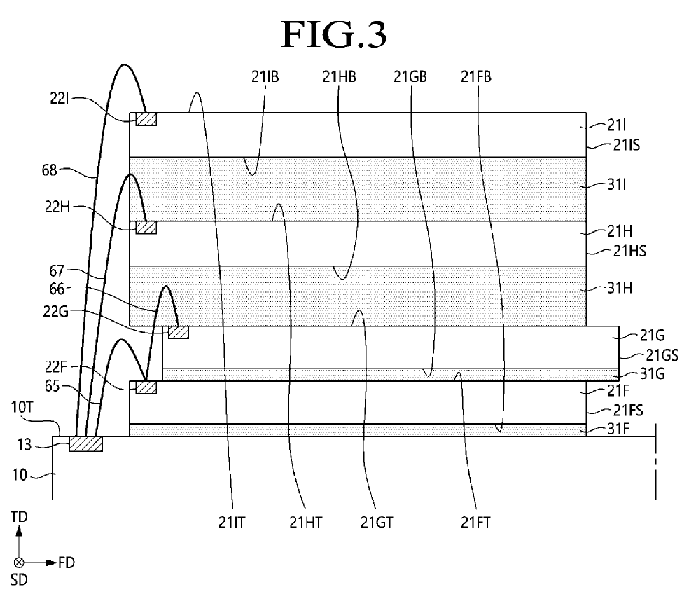

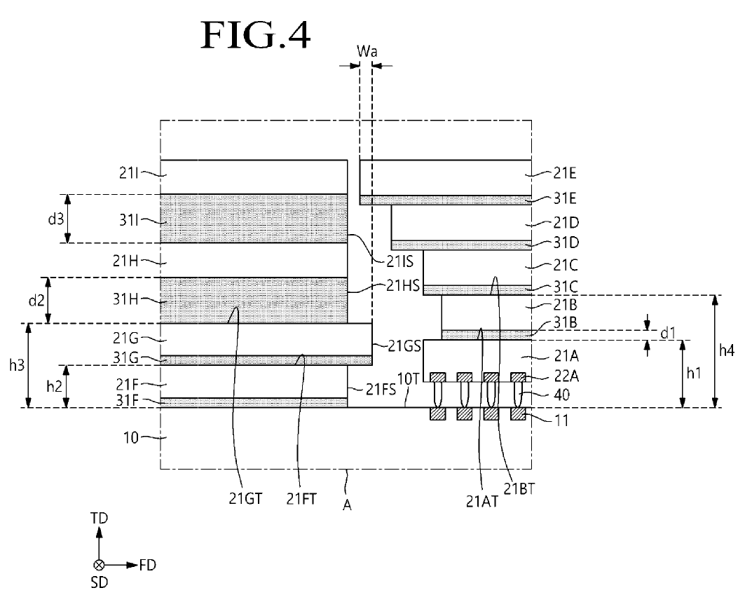

FIG. 1 illustrates a semiconductor package according to an embodiment of the present disclosure, FIG. 2 is an enlarged drawing of a package substrate, a first semiconductor chip, a support member, a first stack, and a first bonding wire of FIG. 1, FIG. 3 is an enlarged drawing of a package substrate, a second stack, a second bonding wire, a third bonding wire, and a fourth bonding wire of FIG. 1, and FIG. 4 is an enlarged drawing of section A of FIG. 1.

Referring to FIG. 1, a semiconductor package 100 according to an embodiment of the present disclosure includes a package substrate 10, a first semiconductor chip 21A, a support member 50, a first stack ST1 and a second stack ST2. In addition, the semiconductor package 100 includes first to eighth bonding wires 61-68, a mold layer 70, and an external connection terminal 80.

The package substrate 10 may include a circuit and/or wiring structure for electrically connecting the first semiconductor chip 21A, the first stack ST1 and the second stack ST2 to the external connection terminal 80. The package substrate 10 may be any one of a printed circuit board (PCB), an interposer, and a redistribution layer.

On the upper surface 10T of the package substrate 10, upper surface substrate pads 11, 12 and 13 for connection with the first semiconductor chip 21A, the first stack ST1, and the second stack ST2 are arranged. In addition, on the lower surface 10B of the package substrate 10, a lower surface substrate pad 14 for connection with an external connection terminal 80 may be arranged. The upper surface substrate pads 11, 12 and 13, and the lower surface substrate pad 14 may be part of the circuit and/or wiring structure of the package substrate 10.

The upper surface substrate pads include a first upper surface substrate pad 11 connected to the first semiconductor chip 21A, a second upper surface substrate pad 12 connected to the first stack ST1, and a third upper surface substrate pad 13 connected to the second stack ST2.

Referring to FIGS. 1 and FIG. 2, the first semiconductor chip 21A is disposed on the package substrate 10. As illustrated in FIG. 1, the first semiconductor chip 21A is disposed offset to one side with respect to the center of the package substrate 10 in a first direction (FD).

A connection electrode 40 is disposed between the first semiconductor chip 21A and the package substrate 10. The first semiconductor chip 21A has a first chip pad 22A on a lower surface 21AB. The first chip pad 22A is electrically connected to a first integrated circuit inside the first semiconductor chip 21A. The connection electrode 40 is disposed below the first chip pad 22A and is connected to the first chip pad 22A and the first upper surface substrate pad 11 of the package substrate 10. The connection electrode 40 electrically connects the first chip pad 22A and the first upper surface substrate pad 11. The connection electrode 40 may be a bump, a solder ball, or a combination thereof, but is not limited thereto.

The first semiconductor chip 21A may be a controller chip for controlling the semiconductor chips 21B, 21C, 21D and 21E included in the first stack ST1 and the semiconductor chips 21F, 21G, 21H and 21I included in the second stack ST2. If the semiconductor chips 21B, 21C, 21D, 21E, 21F, 21G, 21H and 21I included in the first second stack ST1 and the second stack ST2 are memory chips, the first semiconductor chip 21A may be a memory controller chip.

A first adhesive member 31A is attached to a lower surface 50B of a support member 50, and the support member 50 is fixed to an upper surface 10T of a package substrate 10 by the first adhesive member 31A. The support member 50 may be a dummy chip, but is not limited thereto.

The sum of a thickness of the support member 50 and a thickness of the first adhesive member 31A may be substantially the same as the sum of a thickness of the first semiconductor chip 21A and a height of the connection electrode 40. Accordingly, the upper surface 21AT of the first semiconductor chip 21A and the upper surface 50T of the support member 50 may be positioned at substantially the same level in a vertical direction (TD).

The first semiconductor chip 21A is arranged between the support member 50 and the second stack ST2. As illustrated in FIG. 1, the second stack ST2 is arranged on the left side of the first semiconductor chip 21A in the first direction (FD), and the support member 50 is arranged on the right side of the first semiconductor chip 21 in the first direction (FD). The first semiconductor chip 21A is disposed closer to the second stack ST2 than the support member 50.

The first stack ST1 is disposed on the first semiconductor chip 21A and the support member 50, and the second stack ST2 is disposed on the package substrate 10.

The first stack ST1 includes a second semiconductor chip 21B, a third semiconductor chip 21C, a fourth semiconductor chip 21D, and a fifth semiconductor chip 21E, a second adhesive member 31B, a third adhesive member 31C, a fourth adhesive member 31D, and a fifth adhesive member 31E. The second stack ST2 includes a sixth semiconductor chip 21F, a seventh semiconductor chip 21G, an eighth semiconductor chip 21H, and a ninth semiconductor chip 21I, a sixth adhesive member 31F, a seventh adhesive member 31G, an eighth adhesive member 31H, and a ninth adhesive member 31I.

The second semiconductor chip 21B to the ninth semiconductor chip 21I may be the same type of chips. The second to ninth semiconductor chips 21B-21I may be memory chips. The memory may include volatile memory and nonvolatile memory. The volatile memory may include DRAM (Dynamic Random Access Memory) and SRAM (Static Random Access Memory), and the non-volatile memory may include NAND, NOR, PRAM (Phase Change Random Access Memory), and MRAM (Magneto-Resistive Random Access Memory).

Each of the sixth to ninth semiconductor chips 21F-21I may have a structure substantially identical to that of one of the second to fifth semiconductor chips 21B-21E inverted 180 degrees around an axis extending in the vertical direction (TD). The second to ninth semiconductor chips 21B-21I may have the same size in the horizontal direction and the same thickness in the vertical direction (TD).

The second semiconductor chip 21B is disposed on the first semiconductor chip 21A and the support member 50. The second semiconductor chip 21B has a second chip pad 22B on the upper surface 21BT. The second chip pad 22B is electrically connected to a second integrated circuit inside the second semiconductor chip 21B. The second chip pad 22B is arranged on an edge area of the second semiconductor chip 21B opposite to an edge area of one side of the second semiconductor chip 21B close to the second stack ST2, for example, on a right edge area.

The second adhesive member 31B is attached to the lower surface 21BB of the second semiconductor chip 21B, and the second semiconductor chip 21B is fixed on the first semiconductor chip 21A and the support member 50 by the second adhesive member 31B. The second adhesive member 31B is arranged between the first semiconductor chip 21A and the second semiconductor chip 21B, and between the support member 50 and the second semiconductor chip 21B, thereby attaching the first semiconductor chip 21A and the second semiconductor chip 21B, and attaching the support member 50 and the second semiconductor chip 21B.

The third semiconductor chip 21C is disposed on the second semiconductor chip 21B. The third semiconductor chip 21C has a third chip pad 22C on the upper surface 21CT. The third chip pad 22C is electrically connected to the third integrated circuit inside the third semiconductor chip 21C. The third chip pad 22C is disposed on the other edge area of the third semiconductor chip 21C opposite to the one edge area of the third semiconductor chip 21C close to the second stack ST2, for example, on the right edge area.

The third adhesive member 31C is attached to the lower surface 21CB of the third semiconductor chip 21C, and the third semiconductor chip 21C is fixed on the second semiconductor chip 21B by the third adhesive member 31C. The third adhesive member 31C is arranged between the second semiconductor chip 21B and the third semiconductor chip 21C, thereby attaching the second semiconductor chip 21B and the third semiconductor chip 21C.

The fourth semiconductor chip 21D is arranged on the third semiconductor chip 21C. The fourth semiconductor chip 21D has a fourth chip pad 22D on the upper surface 21DT. The fourth chip pad 22D is electrically connected to a fourth integrated circuit inside the fourth semiconductor chip 21D. The fourth chip pad 22D is arranged on the other edge area of the fourth semiconductor chip 21D opposite to the one edge area of the fourth semiconductor chip 21D close to the second stack ST2, for example, on the right edge area.

The fourth adhesive member 31D is attached to the lower surface 21DB of the fourth semiconductor chip 21D, and the fourth semiconductor chip 21D is fixed on the third semiconductor chip 21C by the fourth adhesive member 31D. The fourth adhesive member 31D is disposed between the third semiconductor chip 21C and the fourth semiconductor chip 21D to attach the third semiconductor chip 21C and the fourth semiconductor chip 21D.

The fifth semiconductor chip 21E is disposed on the fourth semiconductor chip 21D. The fifth semiconductor chip 21E has a fifth chip pad 22E on the upper surface 21ET. The fifth chip pad 22E is electrically connected to a fifth integrated circuit inside the fifth semiconductor chip 21E. The fifth chip pad 22E is disposed on the other edge area of the fifth semiconductor chip 21E opposite to the one edge area of the fifth semiconductor chip 21E close to the second stack ST2, for example, on the right edge area.

The fifth adhesive member 31E is attached to the lower surface 21EB of the fifth semiconductor chip 21E, and the fifth semiconductor chip 21E is fixed on the fourth semiconductor chip 21D by the fifth adhesive member 31E. The fifth adhesive member 31E is disposed between the fourth semiconductor chip 21D and the fifth semiconductor chip 21E, and attaches the fourth semiconductor chip 21D and the fifth semiconductor chip 21E.

The second semiconductor chip 21B, the third semiconductor chip 21C, the fourth semiconductor chip 21D, and the fifth semiconductor chip 21E are stacked in a step shape so that the second chip pad 22B, the third chip pad 22C, the fourth chip pad 22, and the fifth chip pad 22E are exposed. The third semiconductor chip 21C is offset to the left with respect to the second semiconductor chip 21B so that the second chip pad 22B is exposed, the fourth semiconductor chip 21D is offset to the left with respect to the third semiconductor chip 21C so that the third chip pad 22C is exposed, and the fifth semiconductor chip 21E is offset to the left with respect to the fourth semiconductor chip 21D so that the fourth chip pad 22D is exposed. The second semiconductor chip 21B, the third semiconductor chip 21C, the fourth semiconductor chip 21D, and the fifth semiconductor chip 21E are stacked in a step shape that goes up to the left, that is, in a step shape toward the second stack ST2.

Referring to FIG. 1 and FIG. 3, the sixth semiconductor chip 21F is disposed on the package substrate 10. The sixth semiconductor chip 21F has a sixth chip pad 22F on the upper surface 21FT. The sixth chip pad 22F is electrically connected to a sixth integrated circuit inside the sixth semiconductor chip 21F. The sixth chip pad 22F is disposed on the other edge area of the sixth semiconductor chip 21F opposite to the one edge area of the sixth semiconductor chip 21F close to the first semiconductor chip 21A, for example, on the left edge area.

The sixth adhesive member 31F is attached to a lower surface 21FB of the sixth semiconductor chip 21F, and the sixth semiconductor chip 21F is fixed on the package substrate 10 by the sixth adhesive member 31F. The sixth adhesive member 31F is disposed between the package substrate 10 and the sixth semiconductor chip 21F, thereby attaching the package substrate 10 and the sixth semiconductor chip 21F.

The seventh semiconductor chip 21G is disposed on the sixth semiconductor chip 21F. The seventh semiconductor chip 21G has a seventh chip pad 22G on the upper surface 21GT. The seventh chip pad 22G is electrically connected to a seventh integrated circuit inside the seventh semiconductor chip 21G. The seventh chip pad 22G is disposed on the other side edge area of the seventh semiconductor chip 21G opposite to the one side edge area of the seventh semiconductor chip 21G close to the first semiconductor chip 21A, for example, on the left edge area.

The seventh adhesive member 31G is attached to a lower surface 21GB of the seventh semiconductor chip 21G, and the seventh semiconductor chip 21G is attached to the sixth semiconductor chip 21F by the seventh adhesive member 31G. The seventh adhesive member 31G is arranged between the sixth semiconductor chip 21F and the seventh semiconductor chip 21G, thereby attaching the sixth semiconductor chip 21F and the seventh semiconductor chip 21G.

The eighth semiconductor chip 21H is arranged on the seventh semiconductor chip 21G. The eighth semiconductor chip 21H has an eighth chip pad 22H on the upper surface 21HT. The eighth chip pad 22H is electrically connected to an eighth integrated circuit inside the eighth semiconductor chip 21H. The eighth chip pad 22H is arranged on the other side edge area of the eighth semiconductor chip 21H opposite to the one side edge area of the eighth semiconductor chip 21H close to the first stack ST1, for example, on the left edge area.

The eighth adhesive member 31H is attached to a lower surface 21HB of the eighth semiconductor chip 21H, and the eighth semiconductor chip 21H is fixed on the seventh semiconductor chip 21G by the eighth adhesive member 31H. The eighth adhesive member 31H is arranged between the seventh semiconductor chip 21G and the eighth semiconductor chip 21H, thereby attaching the seventh semiconductor chip 21G and the eighth semiconductor chip 21H. The eighth adhesive member 31H may be an adhesive layer such as a penetrate wafer backside lamination (PWBL) tape or a P-spacer.

The ninth semiconductor chip 21I is arranged on the eighth semiconductor chip 21H. The ninth semiconductor chip 21I has a ninth chip pad 22I on the upper surface 21IT. The ninth chip pad 22I is electrically connected to a ninth integrated circuit inside the ninth semiconductor chip 21I. The ninth chip pad 22I is arranged on an edge area of the ninth semiconductor chip 21I opposite to one edge area of the ninth semiconductor chip 21I close to the first stack ST1, for example, on a left edge area.

The ninth adhesive member 31I is attached to a lower surface 21IB of the ninth semiconductor chip 21I, and the ninth semiconductor chip 21I is fixed on the eighth semiconductor chip 21H by the ninth adhesive member 31I. The ninth adhesive member 31I is arranged between the eighth semiconductor chip 21H and the ninth semiconductor chip 21I, thereby attaching the eighth semiconductor chip 21H and the ninth semiconductor chip 21I. The ninth adhesive member 31I may be an adhesive layer such as a PWBL tape or a P-spacer.

The sixth semiconductor chip 21F and the seventh semiconductor chip 21G are stacked in a step shape so that the sixth chip pad 22F is exposed. The seventh semiconductor chip 21G is offset to the right with respect to the sixth semiconductor chip 21F to expose the sixth chip pad 22F. The sixth semiconductor chip 21F and the seventh semiconductor chip 21G are stacked in a step shape that goes up to the right, that is, in a step shape toward the first semiconductor chip 21A. For example, a side surface 21GS of the seventh semiconductor chip 21G protrudes further to the first direction FD than the side surface 21FS of the sixth semiconductor chip 21F.

The eighth semiconductor chip 21H is stacked on the seventh semiconductor chip 21G. The eighth semiconductor chip 21H is offset to the left with respect to the seventh semiconductor chip 21G. The eighth semiconductor chip 21H overlaps with the seventh chip pad 22G in the vertical direction (TD). The eighth adhesive member 31H is disposed on the seventh chip pad 22G and covers the seventh chip pad 22G. The side surface 21HS of the eighth semiconductor chip 21H is aligned with the side surface 21FS of the sixth semiconductor chip 21F in the vertical direction (TD).

The ninth semiconductor chip 21I is stacked on the eighth semiconductor chip 21H. The ninth semiconductor chip 21I overlaps with the eighth chip pad 22H in the vertical direction TD. The ninth adhesive member 31I is disposed on the eighth chip pad 22H and covers the eighth chip pad 22H. The side surface 21IS of the ninth semiconductor chip 21I is aligned with the side surface 21HS of the eighth semiconductor chip 21H in the vertical direction (TD). The side surface 21IS of the ninth semiconductor chip 21I is aligned with the side surface 21FS of the sixth semiconductor chip 21F in the vertical direction (TD).

The first bonding wire 61 connects the second substrate pad 12 and the second chip pad 22B. The second bonding wire 62 connects the second chip pad 22B and the third chip pad 22C. The third bonding wire 63 connects the third chip pad 22C and the fourth chip pad 22D. The fourth bonding wire 64 connects the fourth chip pad 22D and the fifth chip pad 22E. The fifth bonding wire 65 connects the third substrate pad 13 and the sixth chip pad 22F. The sixth bonding wire 66 connects the sixth chip pad 22F and the seventh chip pad 22G. At least a portion of a peak section of the sixth bonding wire 66 is impregnated into the eighth adhesive member 31H. The peak section of the sixth bonding wire 66 is a section of its arch-shaped wire loop positioned above the upper surface 21GT of the seventh semiconductor chip 21G.

The seventh bonding wire 67 connects the third substrate pad 13 and the eighth chip pad 22H. At least a portion of a peak section of the seventh bonding wire 67 is impregnated into the ninth adhesive member 31I. The peak section of the seventh bonding wire 67 is a section of its arch-shaped wire loop positioned above the upper surface 21HT of the eighth semiconductor chip 21H. The eighth bonding wire 68 connects the third substrate pad 13 and the ninth chip pad 22I.

The mold layer 70 is formed to cover the first semiconductor chip 21A, the support member 50, the first stack ST1, the second stack ST2, and the first to eighth bonding wires 61-68. The mold layer 70 covers the first semiconductor chip 21A, the support member 50, the first stack ST1, the second stack ST2, and the first to eighth bonding wires 61-68 to protect the first semiconductor chip 21A, the support member 50, the first stack ST1, the second stack ST2, and the first to eighth bonding wires 61-68 from the external environment. The mold layer 70 includes an insulating layer. The insulating layer may include an epoxy molding compound (EMC). The epoxy molding compound may include a resin and a filler.

The external connection terminal 80 is connected to the lower substrate pad 14. The external connection terminal 80 has a ball shape. As another example, the external connection terminal 80 may have various shapes, such as a pillar shape, a combination of a ball shape and a pillar shape, etc. The external connection terminal 80 may include various conductive materials such as a solder material, a metal material, or a combination thereof.

Referring to FIG. 4, the second adhesive member 31B has a thickness of d1 in the vertical direction TD. A thickness of each of the third to seventh adhesive members 31C-31G may be equal to the thickness d1 of the second adhesive member 31B. The eighth adhesive member 31H and the ninth adhesive member 31I have a thickness greater than the second to seventh adhesive members 31B-31G. The eighth adhesive member 31H has a thickness of d2, and the ninth adhesive member 31I has a thickness of d3, and d2 and d3 are greater than d1.

The upper surface 21FT of the sixth semiconductor chip 21F is arranged closer to the upper surface 10T of the package substrate 10 than the upper surface 21AT of the first semiconductor chip 21A. The upper surface 21AT of the first semiconductor chip 21A is arranged at a height of h1 from the upper surface 10T of the package substrate 10, and the upper surface 21FT of the sixth semiconductor chip 21F is arranged at a height of h2 from the upper surface 10T of the package substrate 10, and h2 is smaller than h1.

The distance between the upper surface 10T of the package substrate 10 and the upper surface 21FT of the sixth semiconductor chip 21F is substantially equal to the sum of the thickness of the sixth adhesive member 31F and the thickness of the sixth semiconductor chip 21F. The distance between the upper surface 10T of the package substrate 10 and the upper surface 21AT of the first semiconductor chip 21A is substantially equal to the sum of the height of the connection electrode 40 and the thickness of the first semiconductor chip 21A. The sum of the thickness of the sixth adhesive member 31F and the thickness of the sixth semiconductor chip 21F is smaller than the sum of the height of the connection electrode 40 and the thickness of the first semiconductor chip 21A.

The upper surface 21GT of the seventh semiconductor chip 21G is positioned further from the upper surface 10T of the package substrate 10 than the upper surface 21AT of the first semiconductor chip 21A. The upper surface 21GT of the seventh semiconductor chip 21G is positioned at a height of h3 from the upper surface 10T of the package substrate 10, and h3 is greater than h1.

The distance between the upper surface 10T of the package substrate 10 and the upper surface 21GT of the seventh semiconductor chip 21G is substantially equal to the sum of the thickness of the sixth adhesive member 31F, the thickness of the sixth semiconductor chip 21F, the thickness of the seventh adhesive member 31G, and the thickness of the seventh semiconductor chip 21G. The sum of the thickness of the sixth adhesive member 31F, the thickness of the sixth semiconductor chip 21F, the thickness of the seventh adhesive member 31G, and the thickness of the seventh semiconductor chip 21G is greater than the sum of the height of the connection electrode 40 and the thickness of the first semiconductor chip 21A.

The upper surface 21GT of the seventh semiconductor chip 21G is arranged closer to the upper surface 10T of the package substrate 10 than the upper surface 21BT of the second semiconductor chip 21B. The upper surface 21GT of the seventh semiconductor chip 21G is arranged at a height of h3 from the upper surface 10T of the package substrate 10, and the upper surface 21BT of the second semiconductor chip 21B is arranged at a height of h4 from the upper surface 10T of the package substrate 10, and h3 is smaller than h4.

The distance between the upper surface 10T of the package substrate 10 and the upper surface 21BT of the second semiconductor chip 21B is substantially equal to the sum of the height of the connection electrode 40, the thickness of the first semiconductor chip 21A, the thickness of the second adhesive member 31B, and the thickness of the second semiconductor chip 21B.

The sum of the thickness of the sixth adhesive member 31F, the thickness of the sixth semiconductor chip 21F, the thickness of the seventh adhesive member 31G, and the thickness of the seventh semiconductor chip 21G is smaller than the sum of the height of the connection electrode 40, the thickness of the first semiconductor chip 21A, the thickness of the second adhesive member 31B, and the thickness of the second semiconductor chip 21B.

A section of the seventh semiconductor chip 21G overlaps with a section of the fifth semiconductor chip 21E in the vertical direction (TD). As illustrated in FIG. 4, the seventh semiconductor chip 21G overlaps with the fifth semiconductor chip 21E in the vertical direction (TD) by a width of Wa.

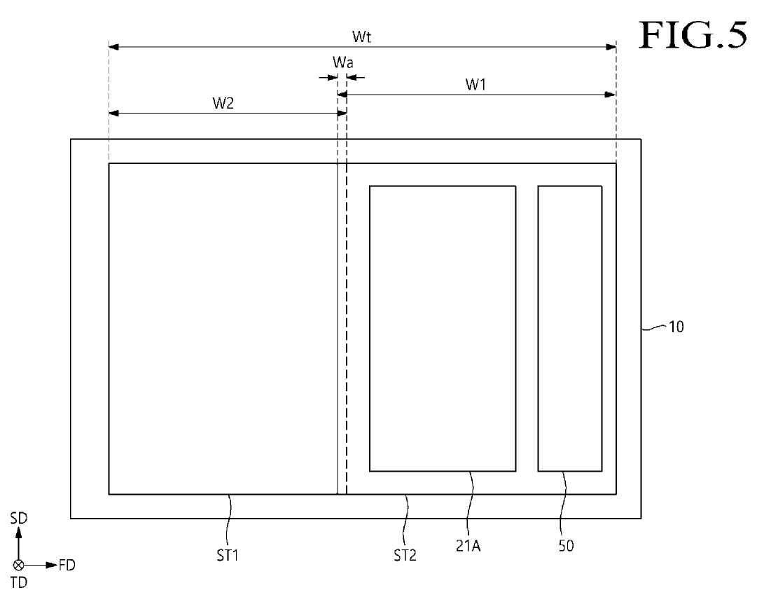

FIG. 5 is a schematic plan view of a semiconductor package according to an embodiment of the present disclosure.

Referring to FIG. 5, the first stack ST1 has a width of W1 in the first direction (FD). The second stack ST2 has a width of W2 smaller than W1 in the first direction (FD).

As described with reference to FIGS. 1 to FIG. 3, the second to fifth semiconductor chips 21B-21E included in the first stack ST1 are stacked in a step shape. Meanwhile, among the sixth to ninth semiconductor chips 21F-21I included in the second stack ST2, only the sixth semiconductor chip 21F and the seventh semiconductor chip 21G are stacked in a step shape, and the eighth semiconductor chip 21H and the ninth semiconductor chip 21I are stacked vertically. Therefore, the width W2 of the second stack ST2 in the first direction (FD) has a smaller size than the width W1 of the first stack ST1 in the first direction (FD).

As illustrated in FIG. 5, if the length of the first stack ST1 in the second direction (SD) and the length of the second stack ST2 in the second direction (SD) are substantially the same, the planar area of the second stack ST2 has a smaller size than the planar area of the first stack ST1.

The first stack ST1 and the second stack ST2 overlap with each other by the width of Wa. Because the first stack ST1 and the second stack ST2 overlap with each other by the width of Wa, the width Wt of the first direction (FD) of the area occupied by the first stack ST1 and the second stack ST2 has a size smaller than the sum of W1 and W2 by Wa. That is, Wt has a value of W1 + W2 – Wa.

According to an embodiment of the present disclosure, the second to fifth semiconductor chips 21B-21E of the first stack ST1 disposed on the first semiconductor chip 21A and the support member 50 are stacked in a step shape so that the second to fifth chip pads 22B-22E are exposed. Accordingly, in an embodiment, the second to fifth adhesive members 31B-31E attached to the lower portions of the second to fifth semiconductor chips 21B-21E are formed with a thin thickness, thereby reducing the height of the semiconductor package. In an embodiment, the eighth semiconductor chip 21H and the ninth semiconductor chip 21I of the second stack ST2 disposed on the package substrate 10 are vertically stacked so that the planar area of the second stack ST2 has a smaller size than the planar area of the first stack ST1, so that the planar area of the semiconductor package can be reduced compared to a case where the semiconductor chips of the second stack are stacked in the same shape as the semiconductor chips of the first stack.

While the detailed embodiments of the present disclosure are disclosed in the present disclosure, those skilled in the art will understand that various modifications, additions, and substitutions related to these embodiments are possible without departing from the scope and technical concepts of the present disclosure. Therefore, the scope of the present disclosure should not be limited to the foregoing embodiments. All changes within the meaning and range of equivalency of the claims are included within their scope.

What is claimed is:

1. A semiconductor package comprising:
a package substrate;
a first semiconductor chip and a support member arranged on the package substrate;
a first stack including a second semiconductor chip, a third semiconductor chip, a fourth semiconductor chip, and fifth semiconductor chip stacked on the first semiconductor chip and the support member;
a second stack including a sixth semiconductor chip, a seventh semiconductor chip, an eighth semiconductor chip, and a ninth semiconductor chip stacked on the package substrate; and
a mold layer covering the first semiconductor chip, the support member, the first stack, and the second stack;
wherein the second semiconductor chip, the third semiconductor chip, the fourth semiconductor chip, and the fifth semiconductor chip are stacked in a step shape so that chip pads of the second semiconductor chip, the third semiconductor chip, the fourth semiconductor chip, and the fifth semiconductor chip are exposed,
wherein the seventh semiconductor chip is offset with respect to the sixth semiconductor chip so that a chip pad of the sixth semiconductor chip is exposed,
wherein the eighth semiconductor chip vertically overlaps with a chip pad of the seventh semiconductor chip,
wherein the ninth semiconductor chip vertically overlaps with a chip pad of the eighth semiconductor chip.

2. The semiconductor package of claim 1, wherein the second semiconductor chip, the third semiconductor chip, the fourth semiconductor chip and the fifth semiconductor chip are stacked in a step shape toward the second stack, and the seventh semiconductor chip is offset with respect to the sixth semiconductor chip in a direction toward the first semiconductor chip.

3. The semiconductor package of claim 1, further comprising:
a first bonding wire connecting the chip pad of the second semiconductor chip with the package substrate;
a second bonding wire connecting the chip pad of the second semiconductor chip with the chip pad of the third semiconductor chip;
a third bonding wire connecting the chip pad of the third semiconductor chip with the chip pad of the fourth semiconductor chip;
a fourth bonding wire connecting the chip pad of the fourth semiconductor chip with the chip pad of the fifth semiconductor chip;
a fifth bonding wire connecting the package substrate with the chip pad of the sixth semiconductor chip;
a sixth bonding wire connecting the chip pad of the sixth semiconductor chip with the chip pad of the seventh semiconductor chip;
a seventh bonding wire connecting the package substrate with the chip pad of the eighth semiconductor chip; and
an eighth bonding wire connecting the package substrate with the chip pad of the ninth semiconductor chip.

4. The semiconductor package of claim 3, further comprising:
a first adhesive member arranged on a lower surface of the second semiconductor chip and attached to the first semiconductor chip and the support member;
a second adhesive member arranged on a lower surface of the third semiconductor chip and attached to the second semiconductor chip;
a third adhesive member arranged on a lower surface of the fourth semiconductor chip and attached to the third semiconductor chip;
a fourth adhesive member arranged on a lower surface of the fifth semiconductor chip and attached to the fourth semiconductor chip;
a fifth adhesive member arranged on a lower surface of the sixth semiconductor chip and attached to the package substrate;
a sixth adhesive member arranged on the lower surface of the seventh semiconductor chip and attached to the sixth semiconductor chip;
a seventh adhesive member arranged on a lower surface of the eighth semiconductor chip and attached to the seventh semiconductor chip; and
an eighth adhesive member arranged on a lower surface of the ninth semiconductor chip and attached to the eighth semiconductor chip.

5. The semiconductor package of claim 4, wherein at least a portion of a peak section of the sixth bonding wire, which is positioned above an upper surface of the seventh semiconductor chip, is impregnated into the seventh adhesive member,
wherein at least a portion of a peak section of the seventh bonding wire, which is positioned above an upper surface of the eighth semiconductor chip, is impregnated into the eighth adhesive member.

6. The semiconductor package of claim 4, wherein the seventh adhesive member and the eighth adhesive member have a thickness greater than the first adhesive member, the second adhesive member, the third adhesive member, the fourth adhesive member, the fifth adhesive member, and the sixth adhesive member.

7. The semiconductor package of claim 1, wherein a side surface of the eighth semiconductor chip and a side surface of the ninth semiconductor chip are aligned with each other in a vertical direction.

8. The semiconductor package of claim 1, wherein a side surface of the eighth semiconductor chip and a side surface of the ninth semiconductor chip are aligned vertically with a side surface of the sixth semiconductor chip.

9. The semiconductor package of claim 1, wherein an upper surface of the sixth semiconductor chip is disposed closer to an upper surface of the package substrate than an upper surface of the first semiconductor chip,
wherein an upper surface of the seventh semiconductor chip is disposed further from the upper surface of the package substrate than the upper surface of the first semiconductor chip.

10. The semiconductor package of claim 1, wherein an upper surface of the seventh semiconductor chip is disposed closer to an upper surface of the package substrate than an upper surface of the second semiconductor chip.

11. The semiconductor package of claim 1, wherein the first semiconductor chip includes a controller chip, and each of the second semiconductor chip to the ninth semiconductor chip includes a memory chip.

12. The semiconductor package of claim 1, wherein the first semiconductor chip is disposed closer to the second stack than to the support member.

13. The semiconductor package of claim 1, further comprising a connection electrode arranged on a lower surface of the first semiconductor chip,
wherein the first semiconductor chip is connected to the package substrate through the connection electrode.

14. A semiconductor package comprising:
a package substrate;
a controller chip and a support member arranged on the package substrate;
a first stack including a first memory chip, a second memory chip, a third memory chip, and a fourth memory chip stacked on the controller chip and the support member;
a second stack including a fifth memory chip, a sixth memory chip, a seventh memory chip, and an eighth memory chip stacked on the package substrate;
a first bonding wire connecting a first upper surface substrate pad of the package substrate and a chip pad of the first memory chip;
a second bonding wire connecting the chip pad of the first memory chip and a chip pad of the second memory chip;
a third bonding wire connecting the chip pad of the second memory chip and a chip pad of the third memory chip;
a fourth bonding wire connecting the chip pad of the third memory chip and a chip pad of the fourth memory chip;
a fifth bonding wire connecting a second upper surface substrate pad of the package substrate and a chip pad of the fifth memory chip;
a sixth bonding wire connecting the chip pad of the fifth memory chip and a chip pad of the sixth memory chip;
a seventh bonding wire connecting the second upper surface substrate pad and a chip pad of the seventh memory chip;
an eighth bonding wire connecting the second upper surface substrate pad and a chip pad of the eighth memory chip;
a mold layer covering the controller chip, the support member, the first stack and the second stack, and the first bonding wire to the eighth bonding wire,
wherein the first memory chip, the second memory chip, the third memory chip and the fourth memory chip are stacked in a step shape so that the chip pad of the first memory chip, the chip pad of the second memory chip, the chip pad of the third memory chip, and the chip pad of the fourth memory chip are exposed,
wherein the sixth memory chip is offset with respect to the fifth semiconductor chip so that the chip pad of the fifth memory chip is exposed,
wherein a side surface of the seventh memory chip and a side surface of the eighth memory chip are vertically aligned with a side surface of the fifth semiconductor chip.

15. The semiconductor package of claim 14, wherein the chip pad of the sixth memory chip vertically overlaps with the seventh memory chip, and the chip pad of the seventh memory chip vertically overlaps with the eighth memory chip.

16. The semiconductor package of claim 14, further comprising:
a first adhesive member disposed between the controller chip and the first memory chip and between the support member and the first memory chip;
a second adhesive member disposed between the first memory chip and the second memory chip;
a third adhesive member disposed between the second memory chip and the third memory chip;
a fourth adhesive member disposed between the third memory chip and the fourth memory chip;
a fifth adhesive member disposed between the package substrate and the fifth memory chip;
a sixth adhesive member disposed between the fifth memory chip and the sixth memory chip;
a seventh adhesive member disposed between the sixth memory chip and the seventh memory chip; and
an eighth adhesive member disposed between the seventh memory chip and the eighth memory chip.

17. The semiconductor package of claim 16, wherein the seventh adhesive member and the eighth adhesive member have a thickness greater than the first adhesive member, the second adhesive member, the third adhesive member, the fourth adhesive member, the fifth adhesive member and the sixth adhesive member.

18. The semiconductor package of claim 16, wherein at least a portion of a peak section of the sixth bonding wire disposed on an upper surface of the sixth memory chip is impregnated into the seventh adhesive member, and at least a portion of a peak section of the seventh bonding wire disposed on an upper surface of the seventh memory chip is impregnated into the eighth adhesive member.

19. The semiconductor package of claim 14, wherein the first memory chip, the second memory chip, the third memory chip, and the fourth memory chip are stacked in a step shape toward the second stack, and the sixth memory chip is offset relative to the fifth memory chip in a direction toward the controller chip.

20. The semiconductor package of claim 14, wherein a section of the sixth memory chip and a section of the fourth memory chip overlap with each other in a vertical direction.
